(19) United States
(12) Patent Application Publication
(10) Pub. No.: US 2026/0190463 A1
(43) Pub. Date: Jul. 2, 2026

(54) FORK FLEX DEVICE

(71) Applicant: INTERNATIONAL BUSINESS MACHINES CORPORATION, Armonk, NY (US)

(72) Inventors: Sagarika Mukesh, ALBANY, NY (US); James Patrick Mazza, Saratoga Springs, NY (US); Ruilong Xie, Niskayuna, NY (US); Albert Manhee Chu, Nashua, NH (US); Nicholas Anthony Lanzillo, Wynantskill, NY (US); Brent Alan Anderson, Jericho, VT (US)

(21) Appl. No.: 19/002,921

(22) Filed: Dec. 27, 2024

(51) Int. Cl. H10D 84/83

(52) U.S. Cl. CPC H10D 84/833

(57) ABSTRACT

A semiconductor device includes a first region including forksheet devices having a first cell height and a second region including nanosheet devices having a second cell height. The forksheet devices and the nanosheet devices share active region rows, and the second cell height is larger than the first cell height.

### BACKGROUND

The present invention generally relates to semiconductor devices and processing methods, and more particularly to forksheet field effect transistor (FET) devices integrated with nanosheet devices.

Forksheet field effect transistors (FETs) include a gate structure that wraps around multiple channel regions, in a fork-like configuration. This structure allows for increased current drive and improved electrostatic control compared to traditional planar or FinFET devices. Forksheet FETs can provide enhanced electrostatic control compared to nanosheet devices, potentially allowing for further scaling of transistor dimensions. This may be achieved through the unique structure of forksheet FETs, which can reduce interference between adjacent transistors. Forksheet FETs provide options for scaling spaces between active areas.

Nanosheet FETs can also provide improved electrostatic control and reduced short-channel effects compared to conventional planar or FinFET architectures. This permits continued scaling of transistor dimensions while maintaining or enhancing performance. The ability to adjust the number and thickness of nanosheets can provide flexibility in device design and optimization for different applications.

However, while similarities exist in fabricating forksheet devices and nanosheet devices, a number of differences in their structure and processing makes it difficult to integrate these devices together on a same semiconductor substrate. These differences can include different cell heights and scaling features between forksheet devices and nanosheet devices. Therefore, an approach for integrating forksheet devices and nanosheet devices on a same semiconductor substrate is needed.

### SUMMARY

In accordance with an embodiment of the present invention, a semiconductor device includes a first region including forksheet devices having a first cell height and a second region including nanosheet devices having a second cell height. The forksheet devices and the nanosheet devices share active region rows and the second cell height is larger than the first cell height.

In other embodiments, the second cell height is about two times larger than the first cell height. A dielectric bar can be disposed centrally relative to active region pillars of the forksheet devices in the first region. The dielectric bar can extend above a gate conductor of the forksheet devices. A single diffusion break can be disposed between the first region and the second region. The nanosheet devices include a double-row gate all around device. The double-row gate all around device can include a recessed dielectric bar disposed below a top surface of a substrate.

In accordance with another embodiment of the present invention, a semiconductor device includes a substrate, a first region including forksheet devices and a second region including nanosheet devices. A single diffusion break separates the first region and the second region.

In other embodiments, the forksheet devices in the first region have a first cell height and the nanosheet devices in the second region have a second cell height, the second cell height being larger than the first cell height. The cell height can be about two times larger than the first cell height. The dielectric bars of the forksheet devices can extend above gate conductors of the forksheet devices.

In accordance with another embodiment of the present invention, a semiconductor device includes a substrate and forksheet devices in a first region, the forksheet devices including dielectric bars at cell boundaries. Nanosheet devices are provided in a second region, the nanosheet devices include recessed dielectric bars between active region pillars.

In other embodiments, the forksheet devices in the first region have a first cell height and the nanosheet devices in the second region have a second cell height, the second cell height being larger than the first cell height. Dielectric bars can be disposed centrally relative to active region pillars of the forksheet devices in the first region.

In accordance with another embodiment of the present invention, a semiconductor device includes a substrate, forksheet devices in a first region and nanosheet devices in a second region. Each nanosheet device includes two active region pillars and a recessed dielectric bar between the two active region pillars.

In other embodiments, the forksheet devices in the first region can have a first cell height and the nanosheet devices in the second region can have a second cell height, the second cell height being larger than the first cell height. The second cell height can be about two times larger than the first cell height. The dielectric bars of the forksheet devices can extend above gate conductors of the forksheet devices. A single diffusion break can separate the first region and the second region.

In accordance with another embodiment of the present invention, a method of fabricating a semiconductor device includes forming dielectric bars at cell boundaries between nanosheet stacks on a substrate; selectively recessing the dielectric bars in a second region while protecting a first region; and forming forksheet devices in the first region and gate-all-around nanosheet devices in the second region, wherein the forksheet devices and the gate-all-around nanosheet devices share active region rows.

In other embodiments, the forksheet devices in the first region have a first cell height and the gate-all-around nanosheet devices in the second region have a second cell height, the second cell height being larger than the first cell height. Forming a single diffusion break between the first region and the second region can be included.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 shows a layout view depicting section line Y1 for cross-sectional view Y1 throughout the FIGS. and showing a nanosheet stack patterned, in accordance with an embodiment of the present invention;

FIG. 2 shows a layout view depicting section line Y1 for cross-sectional view Y1 and showing dielectric bars formed between portions of the nanosheet stack, in accordance with an embodiment of the present invention;

FIG. 3 shows a layout view depicting section line Y1 for cross-sectional view Y1 and showing a hard mask removed and shallow trench isolation regions formed, in accordance with an embodiment of the present invention;

FIG. 4 shows a layout view depicting section lines X, Y1 and Y2 for cross-sectional views X, Y1 and Y2, respectively, and showing a dummy gate material deposited, in accordance with an embodiment of the present invention;

FIG. 5 shows a layout view depicting section lines X, Y1 and Y2 for cross-sectional views X, Y1 and Y2, respectively, and showing a single diffusion break formed to separate regions on a semiconductor device, in accordance with an embodiment of the present invention;

FIG. 6 shows a layout view depicting section lines X, Y1 and Y2 for cross-sectional views X, Y1 and Y2, respectively, and showing a blocking mask protecting a first region, in accordance with an embodiment of the present invention;

FIG. 7 shows a layout view depicting section lines X, Y1 and Y2 for cross-sectional views X, Y1 and Y2, respectively, and showing the dummy gate material recessed to expose the dielectric bars in a second region unprotected by the blocking mask, in accordance with an embodiment of the present invention;

FIG. 8 shows a layout view depicting section lines X, Y1 and Y2 for cross-sectional views X, Y1 and Y2, respectively, and showing the dielectric bars recessed in the second region, in accordance with an embodiment of the present invention;

FIG. 9 shows a layout view depicting section lines X, Y1 and Y2 for cross-sectional views X, Y1 and Y2, respectively, and showing the dummy gate material removed, in accordance with an embodiment of the present invention;

FIG. 10 shows a layout view depicting section lines X, Y1 and Y2 for cross-sectional views X, Y1 and Y2, respectively, and showing replacement metal deposited to form gate structures, in accordance with an embodiment of the present invention; and

FIG. 11 shows a layout view depicting different cell heights for cells in a first region and a second region, in accordance with an embodiment of the present invention.

### DETAILED DESCRIPTION

In accordance with embodiments of the present invention, devices and methods are described which include integrating forksheet field effect transistors (FETs) with nanosheet FETs on a same device or substrate. In an embodiment, the forksheet devices and the nanosheet devices are formed in a same row but include different cell heights. For example, a forksheet device can include a first cell height and the nanosheet can include a second cell height where the first cell height is smaller than the second cell height.

A method for fabricating a semiconductor device with forksheet devices integrated with nanosheet devices can include forming dielectric bars at cell boundaries between two nanosheet stacks. Dummy gates, spacers and source/drain regions are formed. A protecting layer can be formed in a first region, and a second region is opened for additional processing. A partial dummy gate recess is performed to reveal the dielectric bar in the second region so that the dielectric bar can be selectively removed from the second region. The dummy gate and sacrificial semiconductor layers disposed between channels are removed. Forksheet devices are fabricated in the first region. Gate all around (GAA) nanosheet devices are formed in the second region.

In accordance with embodiments of the present invention, an integrated circuit includes first cells with smaller cell height next to second cells with wider cell height. The first cells include forksheet devices with a dielectric bar at cell boundaries (e.g., between N to N regions (N2N) and P to P regions (P2P)). The second cells include nanosheet devices where each N-type FET (NFET) or P-type FET (PFET) of the nanosheet devices includes two active region pillars and a recessed dielectric bar in between the two active region pillars.

In some embodiments, the second cells include a cell height that is about two times larger than a cell height of the first cell. The recessed dielectric bar can include a same dielectric material as a dielectric bar of the first cells (e.g., forksheet devices). The recessed dielectric bar can be lower than a gate. A single diffusion break (SDB) can be disposed between the first cells in a first cell region and the second cells in a second cell region. The dielectric bar that is not recessed can be taller than the gate and is disposed centrally relative to source/drain regions of the first cells.

In accordance with an embodiment of the present invention, a semiconductor device includes a first region including forksheet devices having a first cell height and a second region including nanosheet devices having a second cell height. The forksheet devices and the nanosheet devices share active region rows and the second cell height is larger than the first cell height.

In other embodiments, the second cell height is about two times larger than the first cell height. A dielectric bar can be disposed centrally relative to active region pillars of the forksheet devices in the first region. The dielectric bar can extend above a gate conductor of the forksheet devices. A single diffusion break can be disposed between the first region and the second region. The nanosheet devices include a double-row gate all around device. The double-row gate all around device can include a recessed dielectric bar disposed below a top surface of a substrate.

In accordance with another embodiment of the present invention, a semiconductor device includes a substrate, a first region including forksheet devices and a second region including nanosheet devices. A single diffusion break separates the first region and the second region.

In other embodiments, the forksheet devices in the first region have a first cell height and the nanosheet devices in the second region have a second cell height, the second cell height being larger than the first cell height. The cell height can be about two times larger than the first cell height. The dielectric bars of the forksheet devices can extend above gate conductors of the forksheet devices.

In accordance with another embodiment of the present invention, a semiconductor device includes a substrate and forksheet devices in a first region, the forksheet devices including dielectric bars at cell boundaries. Nanosheet devices are provided in a second region, the nanosheet devices include recessed dielectric bars between active region pillars.

In other embodiments, the forksheet devices in the first region have a first cell height and the nanosheet devices in the second region have a second cell height, the second cell height being larger than the first cell height. Dielectric bars can be disposed centrally relative to active region pillars of the forksheet devices in the first region.

In accordance with another embodiment of the present invention, a semiconductor device includes a substrate, forksheet devices in a first region and nanosheet devices in a second region. Each nanosheet device includes two active region pillars and a recessed dielectric bar between the two active region pillars.

In other embodiments, the forksheet devices in the first region can have a first cell height and the nanosheet devices in the second region can have a second cell height, the second cell height being larger than the first cell height. The second cell height can be about two times larger than the first cell height. The dielectric bars of the forksheet devices can extend above gate conductors of the forksheet devices. A single diffusion break can separate the first region and the second region.

In accordance with another embodiment of the present invention, a method of fabricating a semiconductor device includes forming dielectric bars at cell boundaries between nanosheet stacks on a substrate; selectively recessing the dielectric bars in a second region while protecting a first region; and forming forksheet devices in the first region and gate-all-around nanosheet devices in the second region, wherein the forksheet devices and the gate-all-around nanosheet devices share active region rows.

In other embodiments, the forksheet devices in the first region have a first cell height and the gate-all-around nanosheet devices in the second region have a second cell height, the second cell height being larger than the first cell height. Forming a single diffusion break between the first region and the second region can be included.

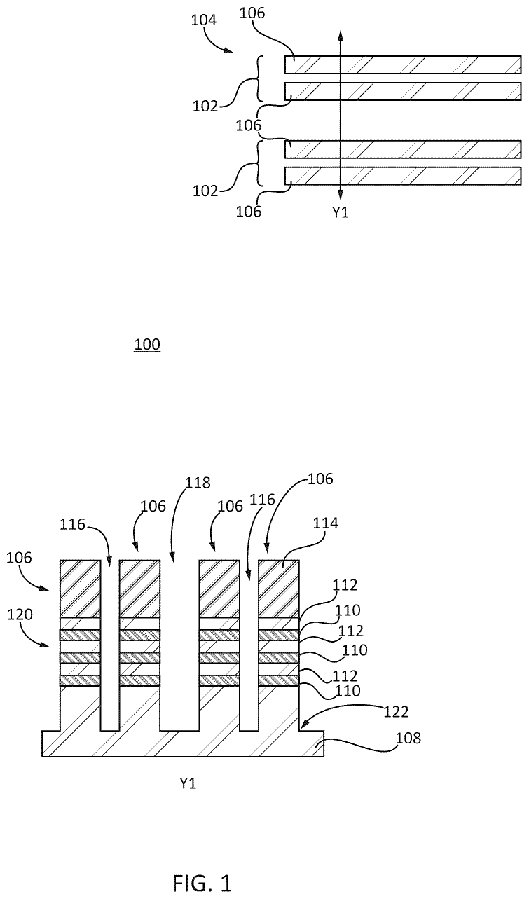

Referring now to the drawings in which like-numerals represent the same or similar elements and initially to FIG. 1, a layout view 104 shows nanosheet stacks 106 patterned on a semiconductor device 100. A section line Y1 cuts through the nanosheet stacks 106. A cross-section view is depicted at section line Y1. The nanosheet stacks 106 have different distances therebetween. The nanosheet stacks 106 in group 102 have a gap 116 while the two groups 102 have a gap 118 therebetween. The gap 118 is larger than the gap 116. The nanosheet stacks 106 will provide a footprint for channels for devices to be formed in later steps.

A substrate 108 can include one or more layers on which a semiconductor device will be fabricated. The substrate 108 can include any suitable substrate structure, e.g., a bulk semiconductor, a semiconductor-on-insulator (SOI) substrate, etc., and preferably includes a monocrystalline semiconductor. In one example, the substrate 108 can include a silicon-containing material. Illustrative examples of Si-containing materials suitable for the substrate 108 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

A nanosheet stack 120 or stacks is/are applied to or formed on the substrate 108. In an embodiment, nanosheets 110, 112 are applied to the substrate 108. The nanosheets 110, 112 include alternating semiconductor layers of different semiconductor materials. The alternating layers can be epitaxially grown using different chemistries to form layers having different properties. In an embodiment, the semiconductor layers of the nanosheets 112 form transistor channels and can include, e.g., Si, although other semiconductor materials can be employed. The semiconductor layers of the nanosheets 110 can include sacrificial layers and can include, e.g., SiGe.

The nanosheet stack 120, which includes the nanosheets 110 and nanosheets 112, can be patterned. In an embodiment, a hard mask 114 may be formed by blanket depositing a layer of hard mask material, providing a patterned photoresist on top of the layer of hard mask material, and then etching the layer of hard mask material to provide the hard mask pattern for etching the nanosheet stack 120. The patterned photoresist can be produced by applying a blanket photoresist layer to the surface of the hard mask material and exposing the photoresist layer to a pattern of radiation, and then developing the pattern into the photoresist layer utilizing resist developer. The pattern in the photoresist layer is transferred to the hard mask by an etch process.

Openings formed through the nanosheet stack 120 can be etched, for example, by an anisotropic etch process, such as a reactive ion etch (RIE) or an ion beam etch (IBE). The etch process can be employed to further etch the substrate 108 to form shallow trenches 122 therein in accordance with the openings.

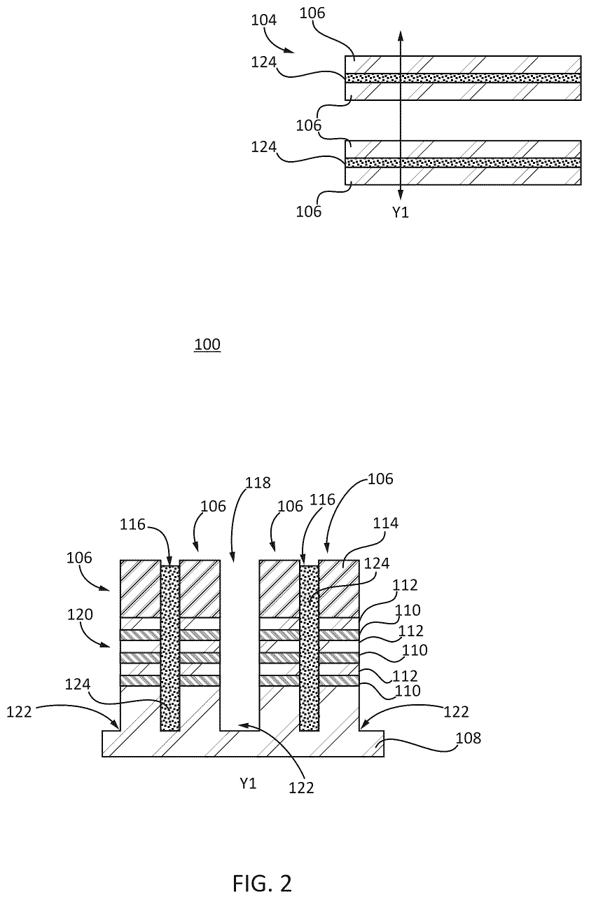

Referring to FIG. 2, dielectric bars 124 are formed in the gaps 116. The dielectric bars 124 can include a dielectric material, such as a nitride, although other dielectric materials can be employed. The dielectric bars 124 can be formed by depositing the dielectric material conformally over the semiconductor device 100. The conformal deposition can include chemical vapor deposition (CVD), atomic layer deposition (ALD) or any other suitable deposition process. The conformal deposition is followed by an isotropic etch process, e.g., a wet etch. The isotropic etch process removes the conformally deposited material from the wider gap 118 and top surfaces of the hard mask 114 but leaves the dielectric material within the gaps 116 with only a slight recess of the dielectric material to form the dielectric bars 124.

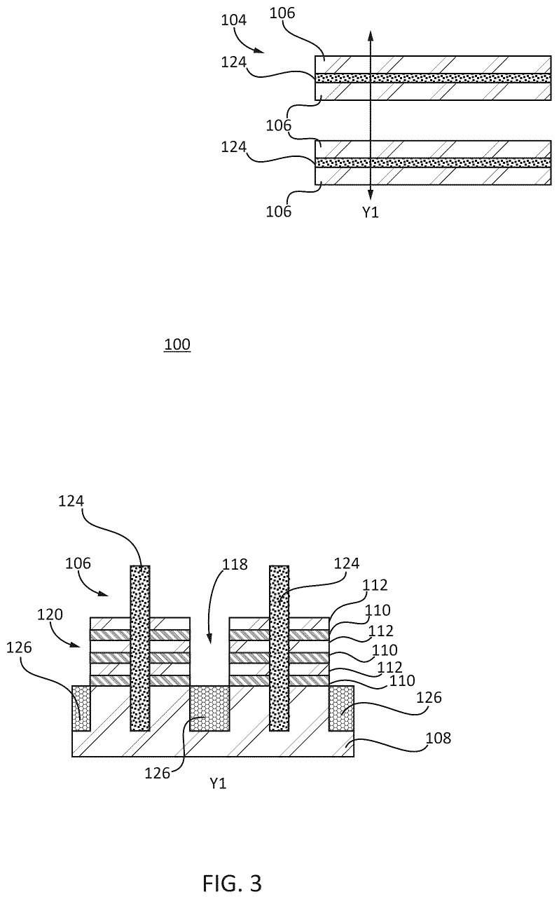

Referring to FIG. 3, shallow trench isolation (STI) regions or STI 126 can be formed in the etched trenches 122. STI 126 can be formed by depositing dielectric material, such as, e.g., SiO₂, SiOₓN_{y}, SiCHO, SiCN, SiCNO or other suitable compounds. STI 126 can be deposited using CVD, although other deposition methods can be employed. The STI 126 can then be etched, e.g., by RIE, to a level of the substrate 108. An optional STI liner can be formed from a different dielectric material than the STI 126 prior to the deposition of the STI 126.

The hard mask 114 is removed by an etch process to remove the hard mask 114 relative to the nanosheets 110, 112, STI 126 and the dielectric bars 124.

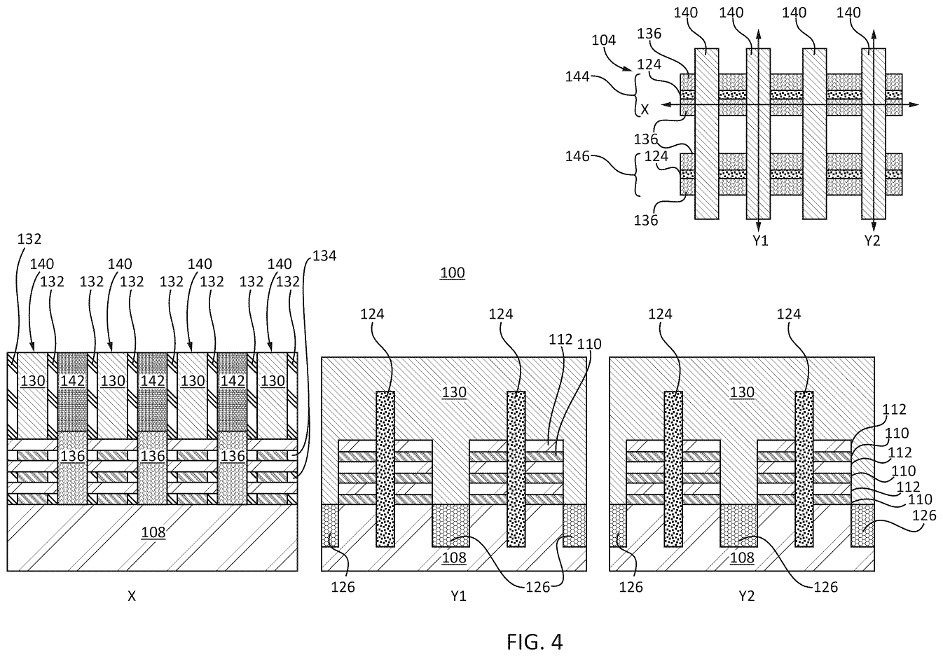

Referring to FIG. 4, the layout view 104 further includes, in addition to section line Y1, section line X and section line Y2 and accompanying cross-sectional views respectively corresponding to the section lines X, Y1 and Y2. Gate structures 140 are depicted which run perpendicular to the dielectric bars 124. A dummy gate material 130 is formed over the nanosheet stacks 120. The dummy gate material 130 can include a polysilicon, amorphous Si or other selectively removeable material. Spacers 132 are formed and can include, e.g., a nitride, although other dielectric materials can be employed. Inner spacers 134 are formed by recessing the nanosheets 110 and depositing a dielectric material in the recesses.

An epitaxial growth process is performed to form source/drain regions 136. The source/drain regions 136 can include, e.g., Si or SiGe. In an embodiment, the source/drain regions 136 can include a polarity and can be designated as N-type or P-type regions. The P-type and N-type regions can have different materials selected for the source/drain regions 136. For example, if the source/drain regions 136 include N-type, then the source/drain regions 136 can include Si. In another example, if the source/drain regions 136 include P-type, then the source/drain regions 136 can include SiGe.

The source/drain regions 136 can be appropriately doped during the formation of the source/drain regions 136 by epitaxial growth. For example, the source/drain regions 136 can be doped by introducing p dopants (e.g., B, Ga, etc.) during epitaxial formation. Similarly, the source/drain regions 136 can be doped by introducing n dopants (e.g., P, As, etc.) during epitaxial formation. The source/drain regions 136 are grown to a height that is above the nanosheet stack 120. The source/drain regions 136 are grown directly on the substrate 108 and therefore benefit from single crystal growth.

In an embodiment, the source/drain regions 136 in region 144 will be designated as N-type and the source/drain regions 136 in region 146 will be designated as P-type. It should be understood that this can be reversed.

A dielectric layer 142, such as, e.g., an interlevel dielectric layer (ILD) is formed on the semiconductor device 100. The dielectric layer 142 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 142 can be deposited using CVD, although other deposition methods can be employed. The dielectric layer 142 is then planarized by a planarization process, such as, e.g., chemical mechanical polishing (CMP).

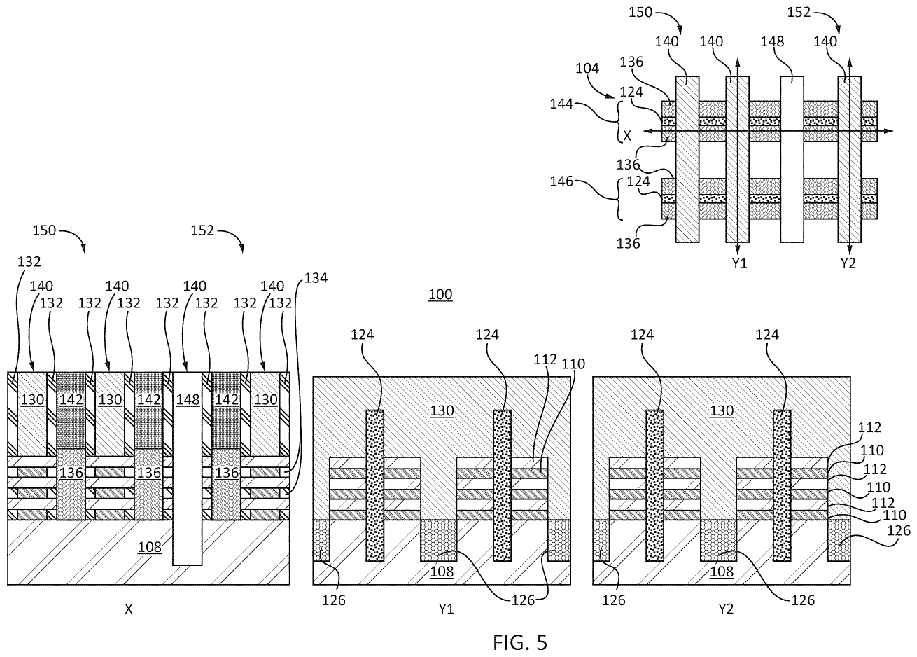

Referring to FIG. 5, the semiconductor device 100 is divided into first regions 150 and second regions 152. The first regions 150 and second regions 152 can be separated by a single diffusion break 148 (SDB). The SDB 148 can be formed by patterning an etch mask and forming an opening at a location or locations where the SDB 148 will be formed. Materials exposed through this opening are exposed to an etch process that selectively etches the opening through a gate structure 140 and down into the substrate 108. The opening is filled with a dielectric layer or layers and planarized to remove material from a top surface of the semiconductor device 100 to form the SDB 148. The SDB 148 can include an oxide although other dielectric materials can be employed.

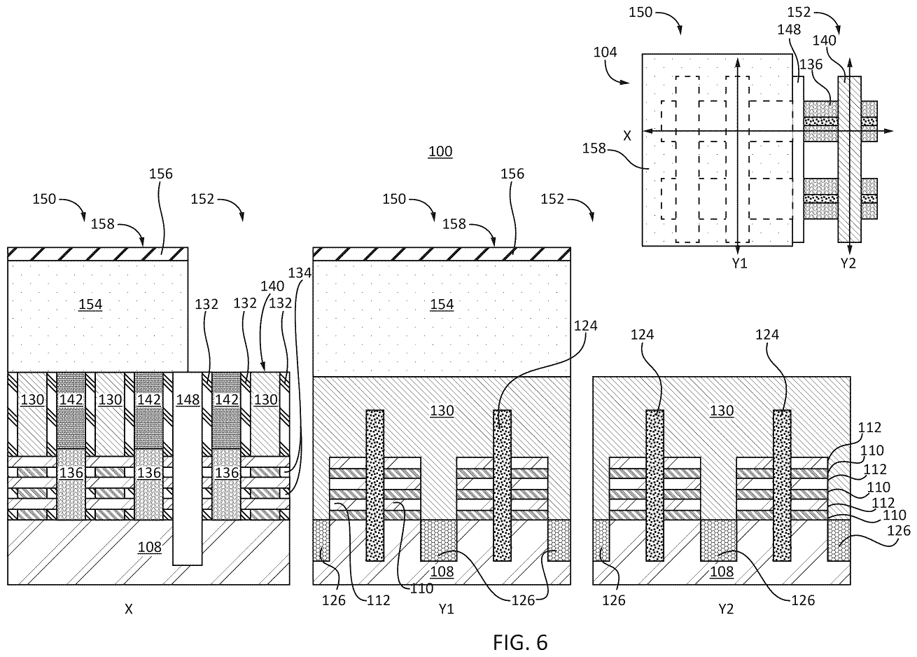

Referring to FIG. 6, a block mask 158 is formed and patterned over the region 150 to expose regions 152. A patternable material is deposited or spun onto a surface of the semiconductor device 100. In an embodiment, an organic planarization layer (OPL) 154 is formed over the semiconductor device 100. In some embodiments, an anti-reflective coating (ARC) layer 156, e.g., a SiARC, may be formed on the OPL 154 followed by a layer of photoresist (not shown) formed on the ARC layer 156. The layer of photoresist can be imaged with an image pattern and developed to form an etch mask. The ARC layer 156 and the OPL 154 can be etched, using an anisotropic etch, such as, e.g., RIE, in accordance with the etch mask to open up the OPL 154 to expose regions 152. The block mask 158 extends to the SDB 148, which separates regions 150 and regions 152.

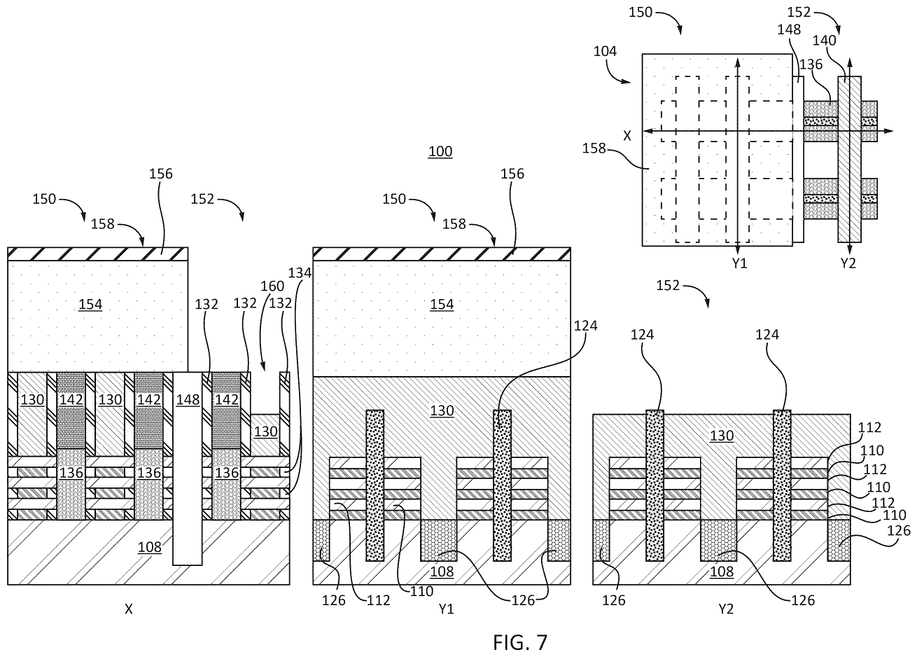

Referring to FIG. 7, with the block mask 158 in place, a selective etch process is performed to recess the dummy gate material 130. The dummy gate material 130 is recessed to a level 160 to expose the dielectric bars in region 152. The selective etch process removes the dummy gate material 130 leaving the dielectric layer 142, spacers 132 and dielectric bars 124 intact.

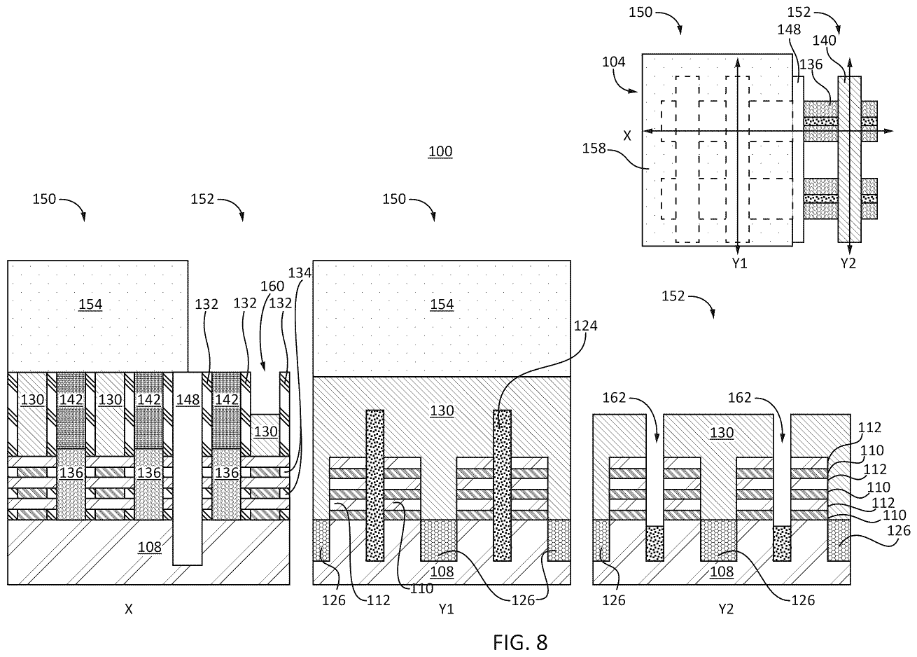

Referring to FIG. 8, with the block mask 158 in place, a selective pull-down etch is performed to recess the dielectric bars 124 in the region 152. The dielectric bars 124 are etched to a position below the top surface of the STI 126 and/or a top surface of the substrate 108. The dielectric bars 124 in region 152 are recessed to below the nanosheets 112 and the nanosheets 110. The selective pull-down etch selectively removes the material of the dielectric bars 124 in region 152 to form openings 162. The selective pull-down etch etches the dielectric bars 124 only, which leaves other structures, e.g., the dummy gate material 130, the nanosheets 112, the nanosheets 110, etc., intact. The selective pull-down etch can include an anisotropic etch, e.g., RIE or IBE, although other etch processes can be employed. The selective pull-down etch removes the ARC layer 156, if present.

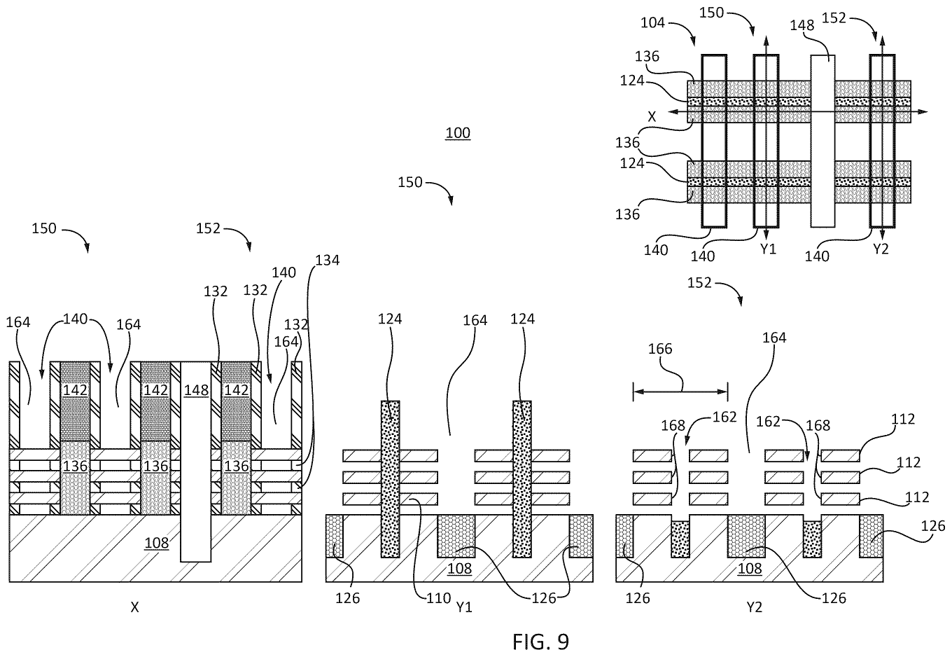

Referring to FIG. 9, the remainder of the block mask 158 is removed by removing the OPL 154. The OPL 154 can be removed by employing an ashing process. A thin oxide spacer (not shown) is formed to protect exposed portions of the nanosheets 112 during the removal of the dummy gate material 130. The dummy gate material 130 is removed to form an open region 164, e.g., by a dry or wet etch process. Next, the nanosheets 110 are exposed by the removal of the thin spacer oxide and any extended gate oxide on the nanosheets 110. Once the nanosheets 110 are exposed, the nanosheets 110 are selectively etched to remove the nanosheets 110 selective to the nanosheets 112.

With the removal of the dummy gate material 130 and the nanosheets 110 and the recessing of the dielectric bar 124 in region 152, openings 162 provide extra surface area for gate conductors that will be formed in later steps. An inner gap formed by openings 162 through the nanosheets 112 increases a dimension 166 of a nanosheet FET to be formed. Surfaces 168 of the nanosheets 112 within the openings 162 are now available as surface area for a replacement metal gate material to be formed.

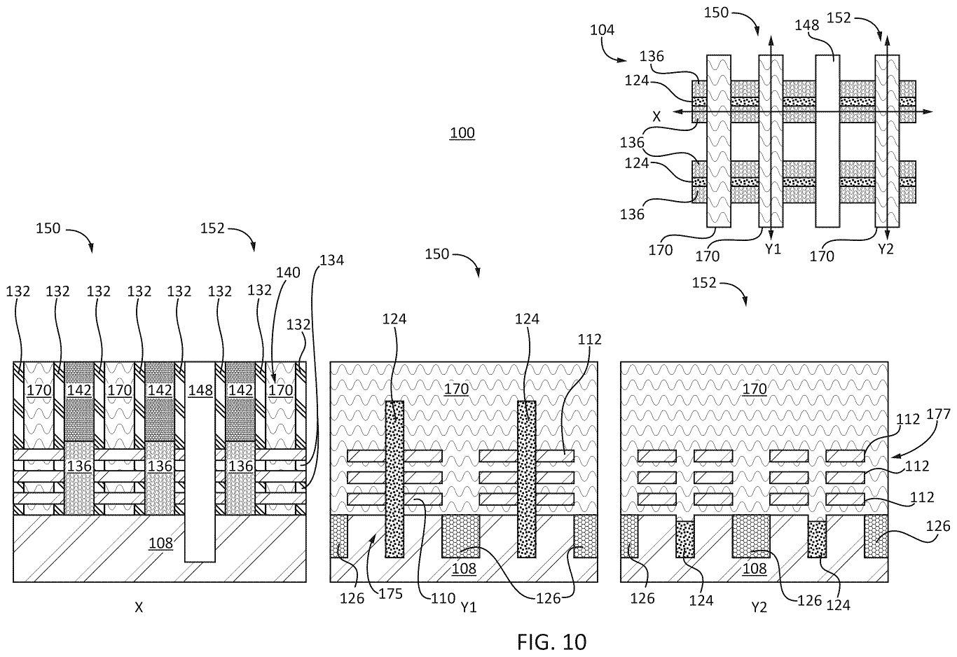

Referring to FIG. 10, a replacement metal gate (RMG) process is performed which fills the open region 164 with a gate conductor 170. A gate dielectric (not shown) is deposited to cover the nanosheets 112 (transistor channels). The RMG process forms High-K Metal Gate (HKMG) structures for selectively activating FETs. The gate conductor 170 can include any conductive metal including, but not limited to W, Ni, Ti, Mo, Ta, Cu, Pt, Ag, Au, Ru, Ir, Rh, and Re, and alloys that include at least one of these conductive materials. The gate conductor 170 can include one or more layers of conductive materials. In one example, a second conductive material may be formed. When a combination of conductive elements is employed, an optional diffusion barrier material such as TaN or WN may be formed between the conductive materials. The gate conductor 170 can be deposited by CVD, plasma enhanced CVD (PECVD), ALD or other suitable deposition process.

The gate conductor 170 fills the openings 162 and is formed over the surfaces 168 of the nanosheets 112 on top of the gate dielectric to form double-row gate all around (GAA) devices 177 in region 152. The gate conductor 170 contacts the dielectric bars 124 that have been recessed in the region 152. Region 150 includes forksheet devices 175. A planarization process (e.g., CMP) can be employed to planarize a free surface of the semiconductor device 100.

Processing continues with the completion of FETs. The region 150 includes forksheet devices 175 while the region 152 includes wider nanosheet devices 177. The processing can include middle of the line (MOL) processing, which includes forming contacts to source/drain regions, gate conductors, etc., followed by back end of the line (BEOL) processing which includes additional metallization layers for accessing the forksheet devices 175 and the wider nanosheet devices 177.

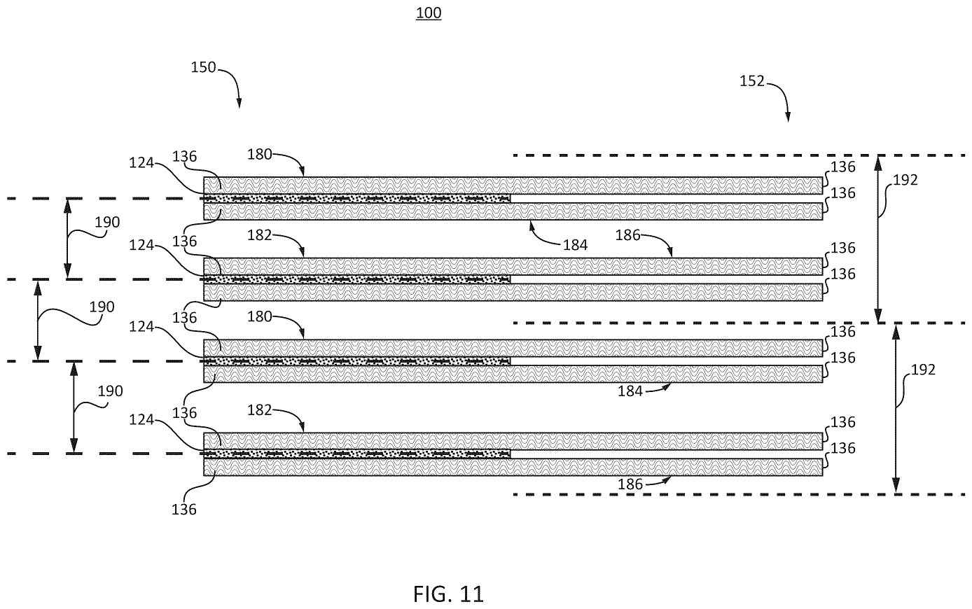

Referring to FIG. 11, a layout view shows regions 150 and 152. Within region 150, NFET pillars 180 and PFET pillars 182 are employed for forksheet devices 175. Within region 152, NFET pillars 184 and PFET pillars 186 are employed for nanosheet devices 177 (e.g., double-row GAA). Region 150 includes cell heights 190 that include complimentary devices, e.g., an NFET pillar 180 and a PFET pillar 182. Region 152 includes cell heights 192 that include complimentary devices, e.g., double-row NFET pillars 184 and double-row of PFET pillars 186. The cell heights 190 of region 150 are one half the cell heights 192 in region 152. The forksheet devices 175 include the dielectric bars 124 while the double-row nanosheet devices 177 include a recessed dielectric bar fill over with gate conductor (FIG. 10).

In accordance with embodiments of the present invention, devices and methods are described which include integrating forksheet devices 175 with nanosheet devices 177 on a same device or substrate. In an embodiment, the forksheet devices 175 and the nanosheet devices 177 are formed in a same row but include different cell heights. For example, the forksheet devices 175 can include a first cell height 190, and the nanosheet devices 177 can include a second cell height 192 where the first cell height is smaller than the second cell height.

The semiconductor device 100 includes an integrated circuit with first cells in region 150 with the smaller cell height 190 next to second cells in region 152 with the wider cell height 192. The first cells include forksheet devices 175 with the dielectric bar 124 at cell boundaries (e.g., between N to N regions (N2N) between NFET pillars 184 and P to P regions (P2P)) (between PFET pillars 186). The second cells include nanosheet devices 177 where each N-type FET (NFET) or each P-type FET (PFET) of the nanosheet devices includes two pillars, and a recessed dielectric bar 124 in between the two pillars.

In some embodiments, the second cells include the cell height 192 about two times larger than the cell height 190 of the first cell. The recessed dielectric bar 124 of the nanosheet devices 177 can include a same dielectric material as a dielectric bar 124 of the first cells (e.g., forksheet devices 175). The recessed dielectric bar 124 can be lower than a gate. A SDB 148 can be disposed between the first cells in region 150 and the second cells in the region 152. The dielectric bar 124 that is not recessed can be taller than the gate and is disposed centrally relative to source/drain regions of the first cells.

Method for fabricating a semiconductor device with forksheet devices integrated with nanosheet devices can include forming dielectric bars at cell boundaries between two nanosheet stacks. Dummy gates, spacers and source/drain regions are formed. A blocking mask can be formed in a first region, and second region is opened for additional processing. A partial dummy gate recess is performed to reveal the dielectric bar in the second region so that the dielectric bar can be selectively removed from the second region. The dummy gate and sacrificial semiconductor layers disposed between channels are removed. Forksheet devices are fabricated in the first region. Gate all around (GAA) nanosheet devices are formed in the second region. The forksheet devices have a different cell height than the nanosheet devices.

Exemplary applications/uses to which the present invention can be applied include but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment,” as well as other variations thereof, means that a particular feature, structure, characteristic, and so forth described in connection with the embodiment is included in at least one embodiment. Thus, the appearances of the phrase “in one embodiment” or “in an embodiment,” as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a first region including forksheet devices having a first cell height; and
a second region including nanosheet devices having a second cell height, wherein the forksheet devices and the nanosheet devices share active region rows and the second cell height is larger than the first cell height.

2. The semiconductor device of claim 1, wherein the second cell height is about two times larger than the first cell height.

3. The semiconductor device of claim 1, further comprising a dielectric bar disposed centrally relative to active region pillars of the forksheet devices in the first region.

4. The semiconductor device of claim 3, wherein the dielectric bar extends above a gate conductor of the forksheet devices.

5. The semiconductor device of claim 1, further comprising a single diffusion break disposed between the first region and the second region.

6. The semiconductor device of claim 1, wherein the nanosheet devices include a double-row gate all around device.

7. The semiconductor device of claim 6, wherein the double-row gate all around device includes a recessed dielectric bar disposed below a top surface of a substrate.

8. A semiconductor device, comprising:
a substrate;
a first region including forksheet devices;
a second region including nanosheet devices; and
a single diffusion break separating the first region and the second region.

9. The semiconductor device of claim 8, wherein the forksheet devices in the first region have a first cell height and the nanosheet devices in the second region have a second cell height, the second cell height being larger than the first cell height.

10. The semiconductor device of claim 9, wherein the second cell height is about two times larger than the first cell height.

11. The semiconductor device of claim 8, further comprising a dielectric bar disposed centrally relative to active region pillars of the forksheet devices in the first region.

12. The semiconductor device of claim 11, wherein the dielectric bar extends above a gate conductor of the forksheet devices.

13. The semiconductor device of claim 8, wherein the nanosheet devices include a double-row gate all around device.

14. The semiconductor device of claim 13, wherein the double-row gate all around device includes a recessed dielectric bar disposed below a top surface of the substrate.

15. A semiconductor device, comprising:
a substrate;
forksheet devices in a first region, the forksheet devices including dielectric bars at cell boundaries; and
nanosheet devices in a second region, the nanosheet devices including recessed dielectric bars between active region pillars.

16. The semiconductor device of claim 15, wherein the forksheet devices in the first region have a first cell height and the nanosheet devices in the second region have a second cell height, the second cell height being larger than the first cell height.

17. The semiconductor device of claim 16, wherein the second cell height is about two times larger than the first cell height.

18. The semiconductor device of claim 15, wherein the dielectric bars of the forksheet devices extend above gate conductors of the forksheet devices.

19. The semiconductor device of claim 15, further comprising a single diffusion break separating the first region and the second region.

20. A semiconductor device, comprising:
a substrate;
forksheet devices in a first region; and
nanosheet devices in a second region, wherein each nanosheet device includes two active region pillars and a recessed dielectric bar between the two active region pillars.

21. The semiconductor device of claim 20, wherein the forksheet devices in the first region have a first cell height and the nanosheet devices in the second region have a second cell height, the second cell height being larger than the first cell height.

22. The semiconductor device of claim 20, further comprising dielectric bars disposed centrally relative to active region pillars of the forksheet devices in the first region.

23. A method of fabricating a semiconductor device, comprising:
forming dielectric bars at cell boundaries between nanosheet stacks on a substrate;
selectively recessing the dielectric bars in a second region while protecting a first region; and
forming forksheet devices in the first region and gate-all-around nanosheet devices in the second region, wherein the forksheet devices and the gate-all-around nanosheet devices share active region rows.

24. The method of claim 23, wherein the forksheet devices in the first region have a first cell height and the gate-all-around nanosheet devices in the second region have a second cell height, the second cell height being larger than the first cell height.

25. The method of claim 23, further comprising forming a single diffusion break between the first region and the second region.
